(19) United States
(12) Patent Application Publication
(10) Pub. No.: US 2009/0017613 A1
(43) Pub. Date: Jan. 15, 2009

(54) METHOD OF MANUFACTURING INTERCONNECT SUBSTRATE AND SEMICONDUCTOR DEVICE

(75) Inventor: Hirokazu HONDA, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, KANAGAWA (JP)

(21) Appl. No.: 12/212,690

(22) Filed: Sep. 18, 2008

Related U.S. Application Data
(62) Division of application No. 11/657,571, filed on Jan. 25, 2007.

(30) Foreign Application Priority Data
Jan. 31, 2006 (JP) 2006-022809

(51) Int. Cl. H01L 21/768

(52) U.S. Cl. 438/637; 257/E21.575

(57) ABSTRACT

An interconnect substrate includes an interconnect, an insulating layer, a non-photosensitive resin layer, a photosensitive resin layer, a first electrode pad, and a second electrode pad. The non-photosensitive resin layer is constructed with a non-photosensitive insulating material. Also, the non-photosensitive resin layer has a first opening. The photosensitive resin layer is constructed with a photosensitive insulating material. Also, the photosensitive resin layer has a second opening. The opening area of the second opening is larger than that of the first opening. The first electrode pad is disposed on the first surface side of the insulating layer. The first electrode pad is exposed to the first opening. The second electrode pad is disposed on the second surface side of the insulating layer. The second electrode pad is exposed to the second opening.

This application is based on Japanese Patent application NO 2006-022809, the content of which is incorporated hereinto by reference.

### BACKGROUND

1. Technical Field

The present invention relates to an interconnect substrate and a semiconductor device using the same as well as to methods of manufacturing those.

2. Related Art

As a conventional interconnect substrate, there is one disclosed in Japanese Laid-open patent publication No. 2004-111536, for example. The interconnect substrate disclosed in this document is manufactured as follows. First, a first insulating layer is formed on one surface of a base metal plate. Next, a first electrode pad to which a semiconductor chip such as an LSI is to be connected is formed on the first insulating layer. Subsequently, an interconnect layer made of a multi-layer interconnect and an insulator covering this is formed on the first electrode pad.

Thereafter, a second electrode pad which is to be connected to a printed interconnect substrate such as a mother board is formed on the interconnect layer. Further, after a second insulating layer is formed on the second electrode pad, an opening (second opening) is formed in the second insulating layer so that the second electrode pad is exposed. Next, the base metal plate is removed by etching. Subsequently, an opening (first opening) is formed in the first insulating layer so that the first electrode pad is exposed. The above process completes a coreless-type multi-layer interconnect substrate.

Here, the second electrode pad that is to be connected to the printed interconnect substrate has an larger area than the first electrode pad to which the semiconductor chip is to be connected. In accordance therewith, the second opening has a larger opening area than the first opening.

As prior art documents related to the present invention, there are, for example, Japanese Laid-open patent publication Nos. 2005-302922, 2005-302943, 2005-302968, and 2005-302969 in addition to Japanese Laid-Open patent publication No. 2004-111536.

### SUMMARY OF THE INVENTION

The present inventor has found out the following problem. That is, in order to form a second opening having a relatively large opening area, it is preferable to use the photolithography method. This is because it is not easy to form an opening having a large opening area by laser processing. Then, in order to use the photolithography method, the second insulating layer in which the second opening is to be formed must be constructed with a photosensitive material.

However, in general, an insulating layer constructed with a photosensitive material is inferior in terms of mechanical strength as compared with an insulating layer constructed with a non-photosensitive material. Decrease in the mechanical strength of the insulating layer leads to decrease in the reliability of the interconnect substrate and in the semiconductor device provided therewith.

According to the present invention, there is provided an interconnect substrate including: an interconnect; an insulating layer covering the interconnect; a first layer provided on a first surface of the insulating layer and constructed with a non-photosensitive insulating material, the first layer having a first opening; a second layer provided on a second surface of the insulating layer, which is a surface opposite to the first surface, and constructed with a photosensitive insulating material, the second layer having a second opening with an opening area larger than that of the first opening; a first electrode pad provided on the first surface side of the insulating layer and exposed to the first opening; and a second electrode pad provided on the second surface side of the insulating layer and exposed to the second opening.

In this interconnect substrate, the second layer is constructed with a photosensitive insulating material. This allows use of the photolithography method in forming the second opening having a relatively large opening area. Therefore, the second opening can be easily formed. On the other hand, the first layer in which the first opening having a relatively small opening area is to be formed is constructed with a non-photosensitive insulating material. Accordingly, the first layer being excellent in mechanical strength can be obtained. Thus, an interconnect substrate facilitating the manufacture thereof and having a high reliability is realized.

According to the present invention, there is also provided a semiconductor device including: the interconnect substrate described above; and a semiconductor chip connected to the first electrode pad. This semiconductor device is provided with the above-described interconnect substrate. Thus, a semiconductor device facilitating the manufacture thereof and having a high reliability is realized.

According to the present invention, there is also provided a method of manufacturing an interconnect substrate, including: forming a first layer constructed with a non-photosensitive insulating material on a supporting substrate; forming a first electrode pad on the first layer; forming an interconnect and an insulating layer covering the interconnect on the first electrode pad; forming a second electrode pad on the insulating layer; forming a second layer constructed with a photosensitive insulating material so as to cover the second electrode pad; forming a second opening in the second layer so that the second electrode pad is exposed; removing the supporting substrate after forming the second opening; and forming a first opening in the first layer after removing the supporting substrate so that the first electrode pad is exposed, the first opening having an opening area smaller than that of the second opening.

According to the present invention, there is also provided a method of manufacturing a semiconductor device, including: forming a first layer constructed with a non-photosensitive insulating material on a supporting substrate; forming a first electrode pad on the first layer; forming an interconnect and an insulating layer covering the interconnect on the first electrode pad; forming a second electrode pad on the insulating layer; forming a second layer constructed with a photosensitive insulating material so as to cover the second electrode pad; forming a second opening in the second layer so that the second electrode pad is exposed; removing the supporting substrate after forming the second opening; forming a first opening in the first layer after removing the supporting substrate so that the first electrode pad is exposed, the first opening having an opening area smaller than that of the second opening; and connecting a semiconductor chip to the first electrode pad that is exposed to the first opening.

In these manufacturing methods, the second layer constructed with a photosensitive insulating material is formed. This allows use of the photolithography method in forming the second opening having a relatively large opening area. Therefore, the second opening can be easily formed. On the other hand, as the layer in which the first opening having a relatively small opening area is to be formed, the first layer constructed with a non-photosensitive insulating material is formed. Accordingly, the first layer being excellent in mechanical strength can be obtained. Thus, an interconnect substrate and a semiconductor device having a high reliability can be easily manufactured.

According to the present invention, an interconnect substrate and a semiconductor device facilitating the manufacture thereof and having a high reliability as well as methods of manufacturing those are realized.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view illustrating the first embodiment of an interconnect substrate and a semiconductor device according to the present invention;

FIGS. 2A and 2B are cross-sectional views illustrating a part of the semiconductor device of FIG. 1;

FIGS. 3A to 3C are process views illustrating one example of a method of manufacturing the semiconductor device of FIG. 1;

FIGS. 4A to 4C are process views illustrating one example of a method of manufacturing the semiconductor device of FIG. 1;

FIGS. 5A to 5C are process views illustrating one example of a method of manufacturing the semiconductor device of FIG. 1;

FIGS. 6A to 6C are process views illustrating one example of a method of manufacturing the semiconductor device of FIG. 1;

FIGS. 7A to 7C are process views illustrating one example of a method of manufacturing the semiconductor device of FIG. 1;

FIGS. 8A to 8C are process views illustrating one example of a method of manufacturing the semiconductor device of FIG. 1;

FIGS. 9A to 9C are process views illustrating one example of a method of manufacturing the semiconductor device of FIG. 1;

FIG. 10 is a cross-sectional view for describing a modified example of the embodiment;

FIG. 11 is a cross-sectional view for describing a modified example of the embodiment;

FIGS. 12A and 12B are cross-sectional views for describing a modified example of the embodiment;

FIG. 13 is a cross-sectional view for describing a modified example of the embodiment;

FIGS. 14A and 14B are cross-sectional views for describing one example of a conventional flip-chip type semiconductor device;

FIGS. 15A to 15C are process views illustrating a method of manufacturing a conventional build-up substrate; and

FIGS. 16A to 16C are process views illustrating a method of manufacturing the conventional build-up substrate.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereafter, with reference to the attached drawings, preferable embodiments of an interconnect substrate and a semiconductor device according to the present invention as well as a method of manufacturing these will be described in detail. Here, in the description of the drawings, like elements are denoted with like reference symbols, and a description thereof will not be repeated.

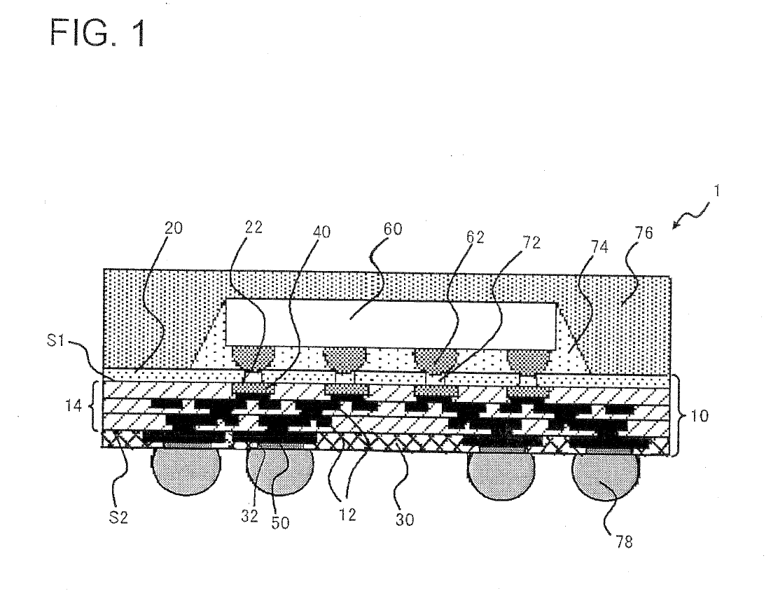

FIG. 1 is a cross-sectional view illustrating the first embodiment of an interconnect substrate and a semiconductor device according to the present invention. The semiconductor device 1 includes an interconnect substrate 10 and a semiconductor chip 60. The interconnect substrate 10 includes an interconnect 12, an insulating layer 14, a non photosensitive resin layer 20 (first layer) a photosensitive resin layer 30 (second layer), an electrode pad 40 (first electrode pad), and an electrode pad 50 (second electrode pad). This interconnect substrate 10 is a coreless multi-layer interconnect substrate that does not have a core substrate.

The interconnect 12 is covered with the insulating layer 14. Also, the interconnect 12 is disposed in a plurality of layers in the insulating layer 14. Namely, the interconnect 12 has a multi-layer interconnect structure. The non-photosensitive resin layer 20 is disposed on the surface S1 (first surface) of the insulating layer 14. The non-photosensitive resin layer 20 is constructed with a non-photosensitive insulating material. The non-photosensitive resin layer 20 may have a multi-layer structure in which a plurality of layers constructed with different non-photosensitive insulating materials are laminated. Also, the non-photosensitive resin layer 20 has an opening 22 (first opening).

The photosensitive resin layer 30 is disposed on the surface S2 (second surface) of the insulating layer 14. The surface S2 is a surface opposite to the surface S1. The photosensitive resin layer 30 is constructed with a photosensitive insulating material. Also, the photosensitive resin layer 30 has an opening 32 (second opening). The opening area of the opening 32 is larger than that of the opening 22.

The electrode pad 40 is disposed on the surface S1 side of the insulating layer 14. Specifically, the electrode pad 40 is disposed in a surface layer on the surface S1 side of the insulating layer 14. The electrode pad 40 is exposed to the opening 22. Namely, the above-described opening 22 is located above the electrode pad 40. This electrode pad 40 is an electrode pad to which the semiconductor chip 60 is to be connected. Also, the material constituting the electrode pad 40 is, for example, a single element Cu.

The electrode pad 50 is disposed on the surface S2 side of the insulating layer 14. Specifically, the electrode pad 50 is disposed on the surface S2 of the insulating layer 14. The electrode pad 50 is exposed to the opening 32. Namely, the above-described opening 32 is located above the electrode pad 50. This electrode pad 50 is an electrode pad that is to be connected to a printed interconnect substrate (not shown) such as a mother board.

Here, the area of the electrode pad 50 is larger than that of the electrode pad 40. The arrangement pitch of the electrode pad 50 is also larger than that of the electrode pad 40. Also, the opening area of the opening 22 is smaller than that of the electrode pad 40. Similarly, the opening area of the opening 32 is smaller than that of the electrode pad 50.

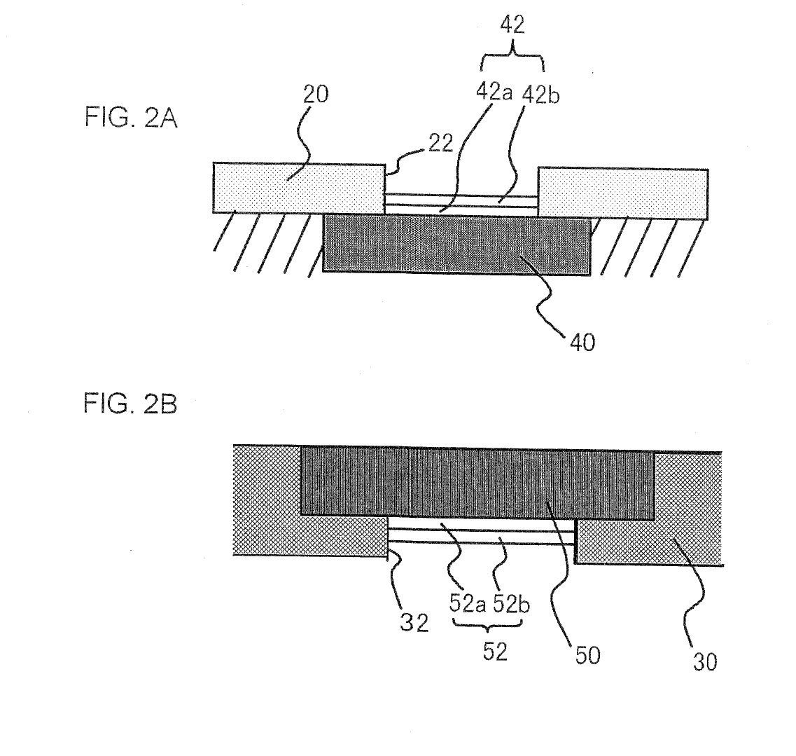

With reference to FIGS. 2A and 2B, the electrode pad 40 and the electrode pad 50 will be described in more detail. These figures are cross-sectional views illustrating a part of the semiconductor device 1. As shown in FIG. 2A, a multi-layer film 42 is disposed on a part of the electrode pad 40 that is exposed to the opening 22. This multi-layer film 42 is made by lamination of a Ni film 42a disposed on the electrode pad 40 and an Au film 42b disposed on the Ni film 42a. Similarly, as shown in FIG. 2B, a multi-layer film S2 is disposed on a part of the electrode pad 50 that is exposed to the opening 32. This multi-layer film 52 is made by lamination of a Ni film 52a disposed on the electrode pad 50 and an Au film 52b disposed on the Ni film 52a.

Returning to FIG. 1, the semiconductor chip 60 is connected to the electrode pad 40 of the interconnect substrate 10. Specifically, the semiconductor chip 60 has a bump electrode 62, and this bump electrode 62 is connected to the electrode pad 40 via a solder 72. Namely, the semiconductor chip 60 is connected in a flip-chip manner to the interconnect substrate 10. The semiconductor chip 60 may be, for example, an LSI.

The gap between the interconnect substrate 10 and the semiconductor chip 60 is filled with an underfill resin 74. Further, the semiconductor chip 60 is covered with a sealing resin 76. Also, to the above-described electrode pad 50, a solder ball 78 functioning as an external electrode terminal of the semiconductor device 1 is connected. However, as an external electrode terminal, a pin-shaped one or a column-shaped one having a cylindrical form can be used instead of the solder ball 78.

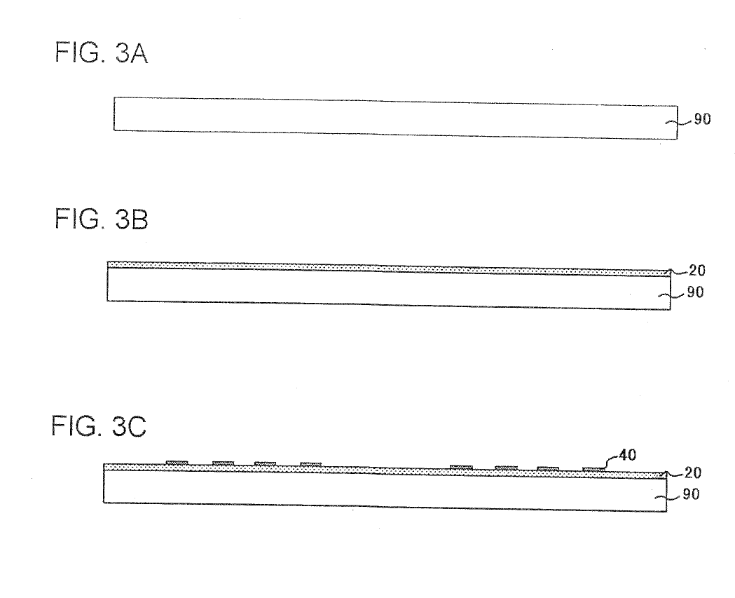

With reference to FIGS. 3A to 9C, one example of a method of manufacturing the semiconductor device 1 will be described as one embodiment of the method of manufacturing an interconnect substrate and a semiconductor device according to the present invention. To sum up, this manufacturing method includes the following steps (a) to (i):

(a) forming the non-photosensitive resin layer 20 on a base substrate 90 (supporting substrate);
(b) forming the electrode pad 40 on the non-photosensitive resin layer 20;
(c) forming the interconnect 12 and the insulating layer 14 covering the interconnect 12 on the electrode pad 40;
(d) forming the electrode pad 50 on the insulating layer 14;
(e) forming the photosensitive resin layer 30 so as to cover the electrode pad S0;
(f) forming the opening 32 in the photosensitive resin layer 30 so that the electrode pad 50 is exposed;
(g) removing the base substrate 90 after forming the opening 32;
(h) forming the opening 22 in the non-photosensitive resin layer 20 after removing the base substrate 90 so that the electrode pad 40 is exposed; and
(i) connecting the semiconductor chip 60 to the electrode pad 40 that is exposed to the opening 22.

More specifically, first, the base substrate 90 is prepared (FIG. 3A). Here, it is preferable to prepare the base substrate 90 having a high flatness and a high mechanical strength. The base substrate 90 is constructed, for example, with a metal material or a metal alloy material such as SUS or Cu as major components.

Next, the non-photosensitive resin layer 20 is formed on one surface of the base substrate 90 (FIG. 3B). The breakage strength and the breakage elongation ratio of the non-photosensitive resin layer 20 are preferably 50 MPa or more and 10% or more, respectively. The non-photosensitive resin layer 20 can be easily formed by the vacuum lamination method or the vacuum pressing method using an insulating resin film in a half-cured state made of an epoxy-based, cyanate-based, or polyolefin-based resin. Also, the non-photosensitive resin layer 20 can be formed by coating with a material in a liquid form such as PI (polyimide).

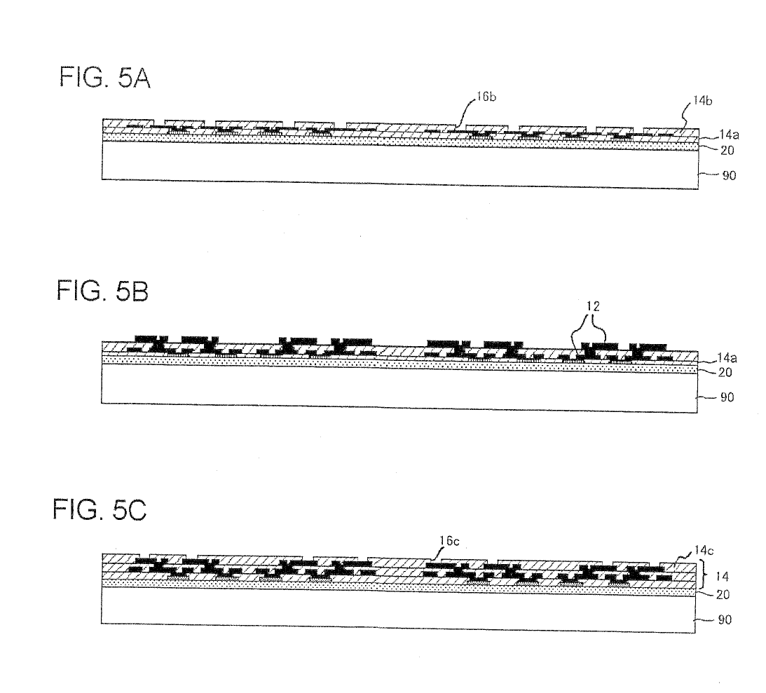

Next, the electrode pad 40 is formed at a predetermined position on the non-photosensitive resin layer 20 (FIG. 5C). For example, the electrode pad 40 made of a Cu material can be formed by the semi-additive processing method using a general non-electrolytic Cu plating seed. Here, assuming an FC (flip-chip) device having a area array arrangement as an LSI (semiconductor chip 60) to be mounted, the FC terminal pitch of the area array arrangement is, for example, about 150 to 250 μm. Also, the diameter of the electrode pad 40 is, for example, about 60 to 100 μm.

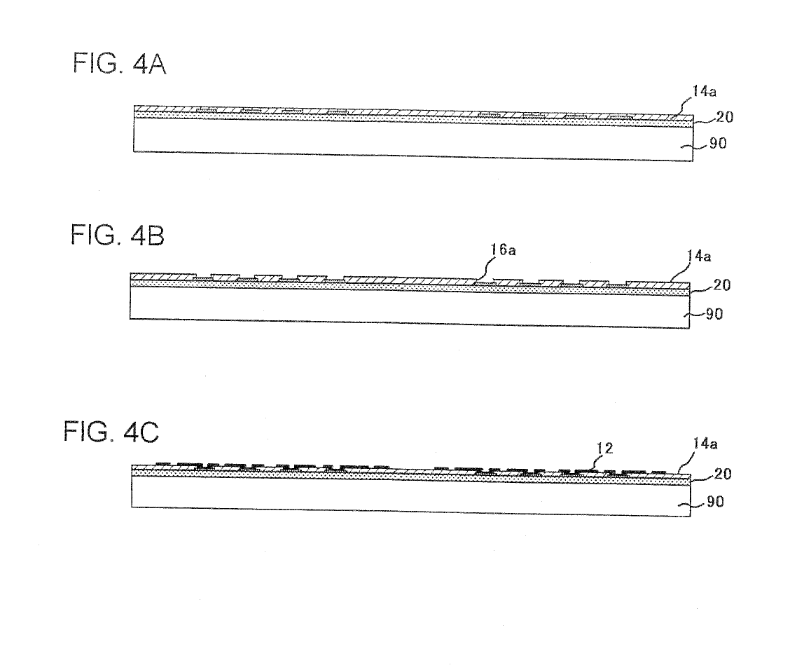

Next, an insulating layer 14a is formed on the electrode pad 40 (FIG. 4A). The insulating layer 14a can be easily formed by the vacuum lamination method or the vacuum pressing method described above. Also, as a different technique for forming the insulating layer 14a, there may be raised a method of forming an insulating material in a liquid form by the spin coating method as well as the CVD (chemical vapor deposition) method and the PVD (physical vapor deposition) method by applying the plasma surface treatment technique, and the like.

Next, a process of partially removing the insulating layer 14a is carried out, whereby an opening 16a is formed (FIG. 4B). Here, when the insulating layer 14a is constructed with a photosensitive material, the opening 16a can be formed by performing the exposure and development process. On the other hand, when the insulating layer 14a is constructed with a non-photosensitive material, the opening 16a can be formed by the laser processing. In the latter case, the opening 16a may be formed with use of the dry etching technique by applying the plasma surface treatment technique after a pattern of a photoresist is formed.

Here, in consideration of the crack-resistance property of the insulating layer 14a, it is preferable to apply a non-photosensitive material generally being excellent in breakage strength and breakage elongation ratio. Also, by considering the reliability of the products, the non-photosensitive resin layer 20 and the insulating layer 14a may be formed with the same non-photosensitive material.

Next, the interconnect 12 is formed on the insulating layer 14a (FIG. 4C). In forming the interconnect 12, the semi-additive processing method can be used. In this processing method, first, a power-feeding layer (seed metal) for electrolytic plating is formed on the entire surface of the insulating layer 14a by non-electrolytic Cu plating or the sputtering method of Ti/Cu or the like. Next, after coating with a photoresist and performing an exposure and development process so that a predetermined interconnect pattern is stripped bare, an interconnect pattern of Cu or the like is formed by using the electrolytic plating method. Subsequently, after the photoresist is peeled off, the underlying power-feeding layer is removed by etching with use of the interconnect pattern as a mask. This completes the interconnect 12.

Thereafter, the above-described steps from forming the insulating layer 14a to forming the interconnect 12 is repeated for a predetermined number of times to obtain a multi layer interconnect structure. Namely, in this example, after an insulating layer 14b is formed on the insulating layer 14a, an opening 16b is formed in the insulating layer 14b (FIG. 5A). The interconnect 12 is formed on the insulating layer 14b (FIG. 5B). Further, after an insulating layer 14c is formed on the insulating layer 14b, an opening 16c is formed in the insulating layer 14c (FIG. 5C). The above process completes the insulating layer 14.

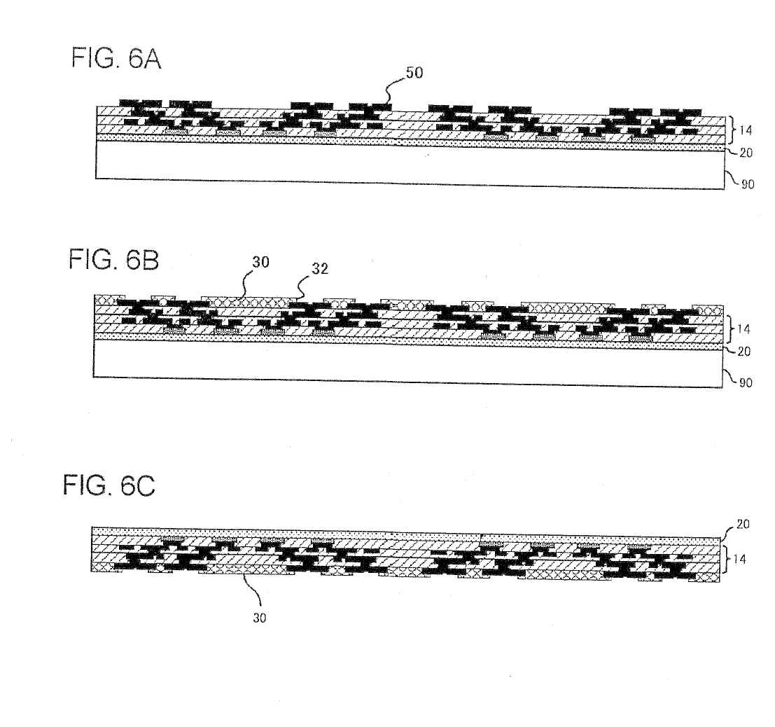

Next, the electrode pad 50 is formed by the above-described semi-additive processing method or the like at a predetermined position on the uppermost layer of the multi-layer interconnect, namely, on the insulating layer 14c (FIG. 6A). Assuming that the electrode pad 50 is to be connected to a mother board, the arrangement pitch of the electrode pad 50 is, for example, about 0.4 to 1.0 mm. Also, the diameter of the electrode pad 50 is, for example, about 0.18 to 0.6 mm.

Next, the photosensitive resin layer 30 is formed on the insulating layer 14 so as to cover the electrode pad 50. Further, an opening 32 is formed in the photosensitive resin layer 30 so that the electrode pad 50 is exposed (FIG. 6B). It is preferable that the opening 32 is formed by the photolithography method.

Next, the base substrate 90 is removed by chemical etching or the like (FIG. 6C). At this time, the non-photosensitive resin layer 20 functions as an etching barrier layer. Here, when the material of the base substrate 90 is a Cu-based metal, the Cu-based metal can be selectively removed by etching with use of an aqueous solution of cupric chloride or an ammonia-based alkali etchant. Also, when the material of the base substrate 90 is an SUS-based metal, the SUS-based metal can be removed by etching with use of an aqueous solution of ferric chloride.

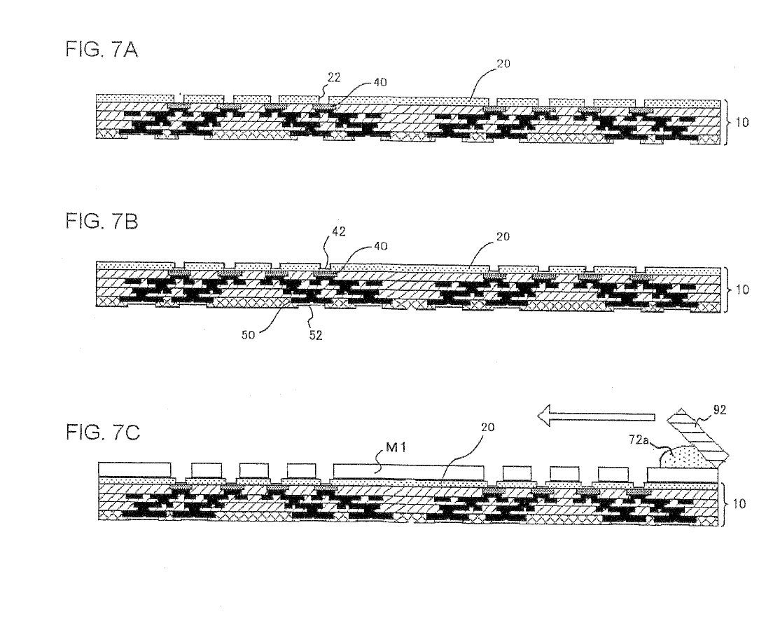

Next, an opening 22 is formed in the non-photosensitive resin layer 20 so that the electrode pad 40 is exposed (FIG. 7A). The opening 22 is preferably formed by the laser processing. Here, when a carbonized resin layer (smear layer) or the like is generated at the bottom of the opening 22 by the laser processing, a desmear treatment may be carried out by permanganate processing or the like after the laser processing.

Next, the multi-layer film 42 is formed on a part of the electrode pad 40 that is exposed to the opening 22, and the multi-layer film 52 is formed on a part of the electrode pad 50 that is exposed to the opening 32 (FIG. 7B). The multi-layer film 42 and the multi-layer film 52 can be formed by the non-electrolytic plating method. The above completes the interconnect substrate 10. Here, an electrical test (open/short test) of the interconnect substrate 10 may be carried out by using a probe for electrical test with use of the electrode pad 40 and the electrode pad 50 on which the multi-layer film 42 and the multi-layer film 52 are formed, respectively, as electrodes.

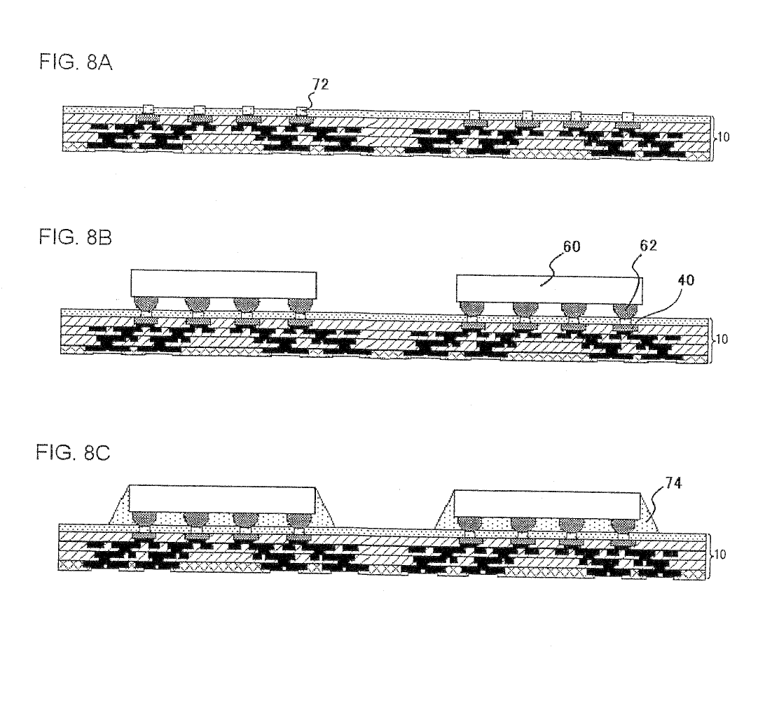

Subsequently, after a printed mask M1 is formed on the non-photosensitive resin layer 20, an ordinary printing process is carried out using a solder paste 72a and a printing squeegee 92 (FIG. 7C). After the solder paste 72a is placed in the opening 22 by this process, a soldering process such as IR reflow is carried out to form the solder 72 (preparatory solder part) (FIG. 8A).

Next, the semiconductor chip 60 is mounted in a flip-chip manner on the electrode pad 40 of the interconnect substrate 10 (FIG. 8B). At this time, when the bump electrode 62 of the semiconductor chip 60 is a solder containing a metal material such as Sn or Pb as a major component, the semiconductor chip 60 can be mounted in a flip-chip manner by the heated reflow process using a flux. Also, when the bump electrode 62 is a solder containing a metal material such as Au or In as a major component, the semiconductor chip 60 can be mounted in a flip-chip manner by the thermal press-bonding method.

Thereafter, the gap between the semiconductor chip 60 and the interconnect substrate 10 is filled with the insulating underfill resin 74 (FIG. 8C). In this example, the side surface of the semiconductor chip 60 is also covered with the underfill resin 74. The underfill resin 74 can be formed by a sealing technique using an underfill material in a liquid form, or by a transfer sealing technique, or the like. By providing the underfill resin 74, the semiconductor chip 60 and the interconnect 10 as well as the connection part thereof can be effectively protected.

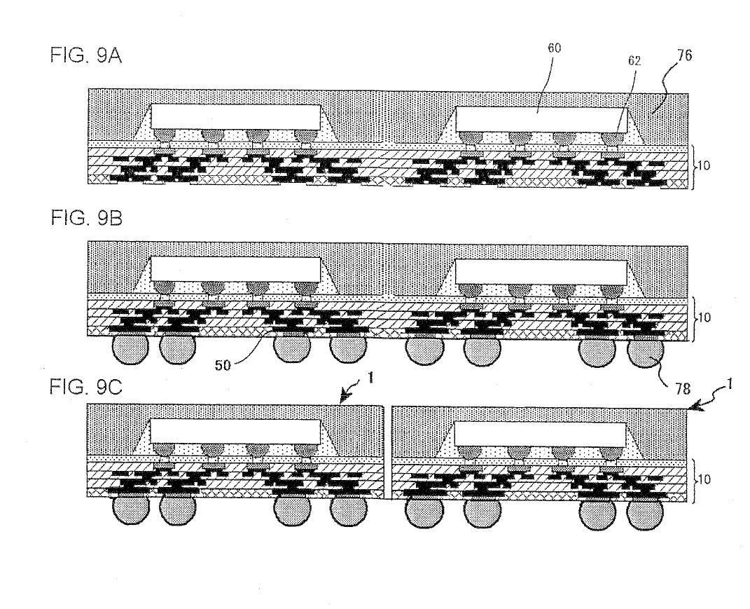

Thereafter, the sealing resin 76 is formed on the interconnect substrate 10 so as to cover the semiconductor chip 60 (FIG. 9A). The sealing resin 76 can be formed by a transfer sealing technique, by an injection sealing technique, or the like. By providing the sealing resin 76, improvement in the mechanical strength and improvement in the humidity resistance as a semiconductor package of the semiconductor device 1 can be achieved.

Thereafter, the solder ball 78 containing a metal material such as Sn as a major component is connected to the electrode pad 50 (FIG. 9B). The solder ball 78 can be connected, for example, by applying a flux selectively onto the electrode pad 50 and then mounting the solder ball 78 and performing a heat treatment by the IR reflow process.

Thereafter, a cutting and separating technique using a dicing blade or the like is used to divide the wafer into individual pieces (FIG. 9C). The above process completes the semiconductor device 1.

The effects of the present embodiment will be described. In the interconnect 10, the photosensitive resin layer 30 is constructed with a photosensitive insulating material. This allows use of the photolithography technique in forming the opening 32 having a relatively large opening area. Therefore, the opening 32 can be easily formed.

On the other hand, one may consider forming the opening 32 by laser processing. However, regarding the laser processing, the upper limit of the processing diameter per one shot is about 100 μm, so that it is not suitable for forming the electrode pad 50 having a diameter of about 180 to 600 μm. Also, it may be considered to form the opening 32 by a dry etching technique. However, a dry etching apparatus adopting the vacuum technique is generally extremely expensive. Moreover, a process of coating with a photoresist and performing exposure and development will be needed. This raises a problem of inviting an increase in the production costs. Due to these reasons, it is preferable to use the photolithography method in forming the opening 32.

On the other hand, the non-photosensitive resin layer 20 in which the opening 22 having a relatively small opening area is formed is constructed with a non-photosensitive insulating material. Generally, a non-photosensitive material is excellent in mechanical strength and in breakage elongation ratio as compared with a photosensitive material. For this reason, by adopting the non-photosensitive resin layer 20, defects such as insulating resin cracks can be refrained from being generated in the interconnect substrate 10, thereby improving the reliability of the interconnect substrate 10. Thus, the interconnect substrate 10 facilitating the manufacture thereof and having a high reliability is realized. Also, the semiconductor device 1 is provided with this interconnect substrate 10. Thus, the semiconductor device 1 facilitating the manufacture thereof and having a high reliability is realized.

The opening area of the opening 22 is smaller than the area of the electrode pad 40. For this reason, a part of the surface (surface exposed to the opening 22) of the electrode pad 40 is constructed so as to be covered with the non-photosensitive resin layer 20. This prevents the electrode pad 40 from being peeled off from the insulating layer 14. Similarly, the opening area of the opening 32 is smaller than the area of the electrode pad 50. For this reason, a part of the surface (surface exposed to the opening 32) of the electrode pad 50 is constructed so as to covered with the photosensitive resin layer 30. This prevents the electrode pad 50 from being peeled off from the insulating layer 14.

The multi-layer film 42 (See FIG. 2A) is disposed on a part of the electrode pad 40 that is exposed to the opening 22. This improves the stability of solder bonding in forming the solder 72. Also, in the case of performing the above-described electrical test, the contact resistance between the electrode pad 40 and the probe for testing can be stabilized. Similarly, the multi-layer film 52 (See FIG. 2B) is disposed on a part of the electrode pad 50 that is exposed to the opening 32. This improves the stability of solder bonding in forming the solder ball 78. Also, in the case of performing the above-described electrical test, the contact resistance between the electrode pad 50 and the probe for testing can be stabilized.

The solder 72 is provided as a preparatory solder part in the opening 22. This improves the stability of the soldering process in connecting the semiconductor chip 60 in a flip-chip manner. In particular, when the size of the semiconductor chip 60 is 15 mm square or more, the degree of parallelness of the electrode pad 40 tends to be severe due to warpage of the interconnect substrate 10. For this reason, when considering the production process, it will be important to form the solder 72. On the other hand, when the size of the semiconductor chip 60 is less than 15 mm square, the above-described tendency is not seen, so that it is not important to form the solder 72.

Also, in the manufacturing method of the present embodiment, a multi-layer interconnect layer is formed on the base substrate 90. This restricts the multi-layer interconnect layer mechanically to the base substrate 90, so that a high flatness can be maintained. Further, the multi-layer interconnect layer has an excellent stability in term of thermal distribution. Therefore, a manufacturing method is realized that is excellent in production yield and suitable for forming interconnects having a fine pitch.

On the other hand, in the case of an ordinary build-up substrate, the pattern pitch has a limit of 10 μm/10 μm in line and space because of the warpage or fine irregularity of FR-4, 5 or BT-based core substrate. Moreover, since the warpage of the core substrate is large, variation in the focal depth during the pattern exposure is liable to occur, resulting in the deterioration of the stability of the manufacturing process. Therefore, the conventional manufacturing methods have a technical limit in view of forming a fine pattern and in view of drastic improvement of the production costs.

Also, in the manufacturing method of the present embodiment, the non-photosensitive resin layer 20 functions as an etching harrier layer in removing the base substrate 90. This can protect the electrode pad 40. Therefore, the stability of the process of manufacturing the interconnect substrate 10 will be improved, thereby improving the productivity.

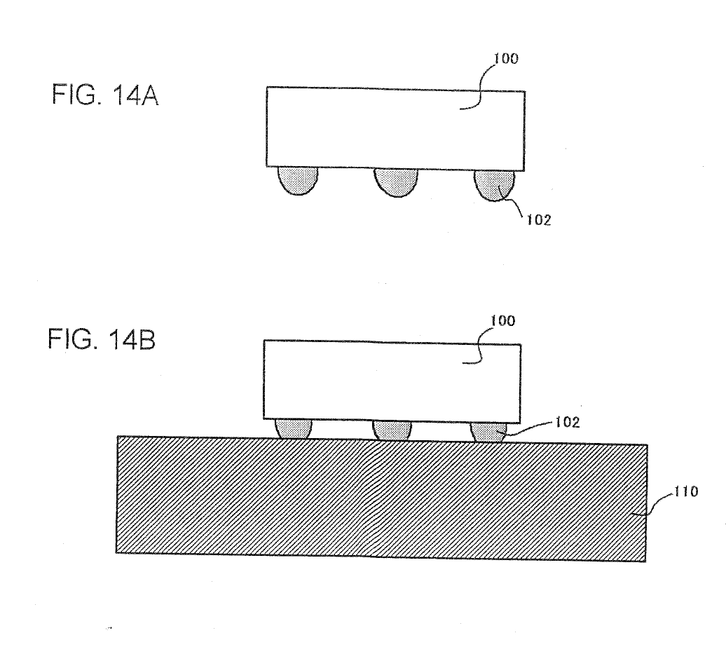

With reference to FIGS. 14A and 14B, one example of a conventional flip-chip type semiconductor device will be described. This semiconductor device includes a semiconductor chip 100 shown in FIG. 14A. On the surface of the semiconductor chip 100, protruding bumps 102 constructed with an electrically conductive material such as solder, Au, or an Sn—Ag-based alloy are formed. The bumps 102 are formed on the external terminals that are formed in a predetermined arrangement on the peripheries of the chip or on the active region, namely, on the external terminals formed in an area array arrangement.

As shown in FIG. 14B, this semiconductor chip 100 is mounted on a multi-layer interconnect substrate 110. On this multi-layer interconnect substrate 110, electrode pads (not shown) arranged in the same pattern as the arrangement pattern of the bumps 102 are formed. In mounting the semiconductor chip 100 on the multi-layer interconnect substrate 110, when solder is used as a material of the bumps 102, an IR reflow process using a flux is typically carried out.

However, after the semiconductor chip is mounted on the multi-layer interconnect substrate, there has been a problem that, due to mismatch of the linear expansion coefficient between these, the temperature cycle characteristics are inferior particularly among the mounting reliabilities. In order to solve the problem, the following measures have been conventionally taken.

First, in order to approximate the linear expansion coefficient of the multi-layer interconnect substrate to the linear expansion coefficient of silicon, there have been attempts to minimize the mismatch of the linear expansion coefficient to improve the mounting reliability by using a ceramic-based material such as ALN, mullite, or glass ceramics, which is an expensive material. These attempts have been effective in view of the improvement in the mounting reliability. However, since an expensive ceramic-based material is used as a material of the multi-layer interconnect substrate, use of the interconnect substrate has been limited generally to application of a high-end supercomputer or a large-scale computer.

On the other hand, in recent years, as a technique that can improve the mounting reliability with use of a multi-layer interconnect substrate using an organic material having a relatively low price and having a large linear expansion coefficient in flip-chip mounting, a technique of placing an underfill resin between a semiconductor chip and a multi-layer interconnect substrate using an organic material is becoming popular. This technique is a technique such that, by placing an underfill resin between a semi conductor chip and a multi-layer interconnect substrate using an organic material, a shear stress acting on a bump connection part located between the semiconductor chip and the multi-layer interconnect substrate using an organic material is dispersed thereby to improve the mounting reliability.

According to this technique, by allowing an underfill resin to intervene between the semiconductor chip and the multi-layer interconnect substrate using an organic material, a multi layer interconnect substrate having a low price and using an organic material can be used. In the meantime, however, the following problem is raised when a void is present in the underfill resin or when an adhesion property at the interface between the underfill resin and the semiconductor chip or at an interface between the underfill resin and the multi-layer interconnect substrate using an organic material is poor. Namely, it is a problem that an interface exfoliation phenomenon is induced in the moisture-absorbing reflow process of the product, thereby generating defects in the product. For this reason, the above-described technique cannot generally promote the cost reduction of the flip-chip type semiconductor devices.

Also, generally in a flip-chip type semiconductor device, a multi-layer interconnect substrate referred to as a build-up substrate is typically used as a multi-layer interconnect substrate using an organic material in view of the minimum pitch of the bump arrangement pattern and the number of pins.

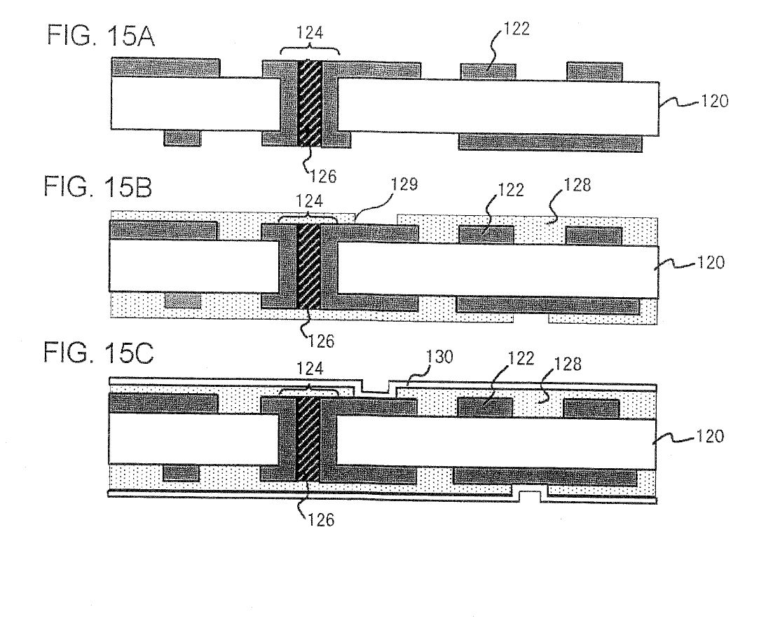

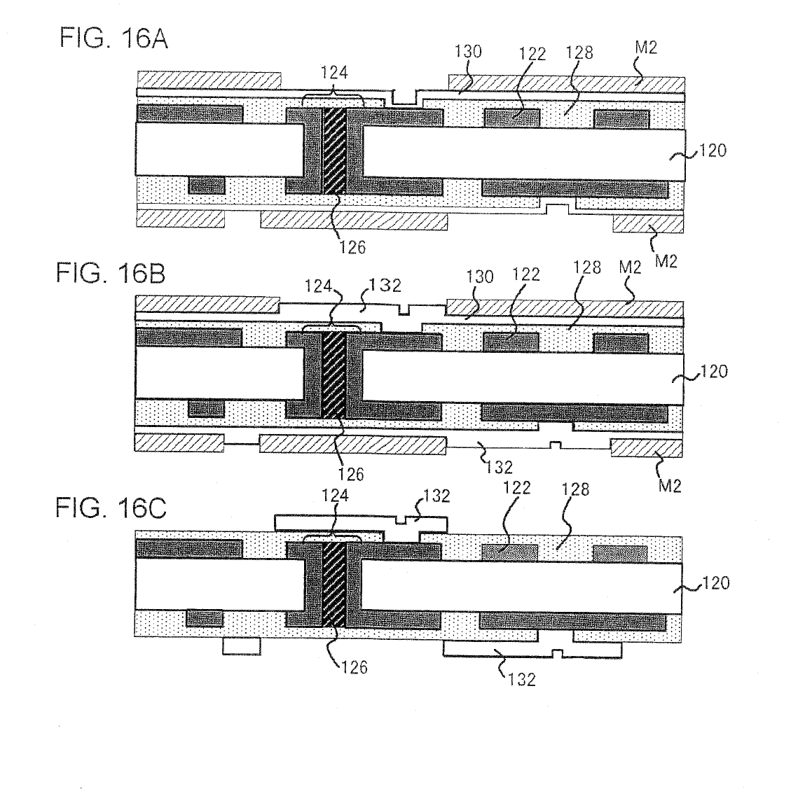

With reference to FIGS. 15A to 16C, a method of producing a conventional build-up substrate will be described. First, a core substrate 120 is prepared in which a Cu foil having a thickness of 10 to 40 μm is bonded on both surfaces of an insulating glass epoxy base material such as represented by FR4, FR5, or BT substrate (FIG. 15A). This Cu foil is subjected to a patterning process to become an interconnect 122. Further, in order to establish electrical connection between the upper and lower interconnects 122, a through-hole part 124 is formed. The through-hole part 124 can be formed by boring through a drilling process or the like and then performing a through-hole plating process. At this time, in consideration of the process stability in later steps and the product quality stability of the substrate, the inside of the through-hole part 124 is typically filled with an insulating resin 126 for filling a through-hole.

Next, an insulating resin 128 is formed on the interconnects 122 that are present above and below the core substrate 120. Thereafter, an opening 129 is formed at a predetermined position of the insulating resin 128 by the chemical etching method using a photoresist technique or by the laser processing technique or the like (FIG. 15B). Next, in order to ensure electrical connection between a power-feeding layer of an electrolytic Cu plating process and the interconnect 122 on the core substrate 120, a metal thin-film layer 130 is formed by the sputtering method using a metal such as Ti/Cu, the non-electrolytic Cu plating method, or the like (FIG. 15C).

Thereafter, in order to form an interconnect pattern by the electrolytic Cu plating process, a mask M2 such as a photoresist or a dry film having a thickness of about 20 to 40 μm is formed on the metal thin-film layer 130, and an exposure and development process is carried out (FIG. 16A). Thereafter, an interconnect pattern part 132 is formed by the electrolytic Cu plating process using the metal thin-film layer 130 as a power-feeding layer (FIG. 16B). Next, after peeling the mask M2 off, the metal thin-film layer 130 is removed by a wet etching process using the interconnect pattern part 132 as a mask, so as to let the interconnect pattern part 132 be electrically independent (FIG. 16C). The above-described steps from forming the insulating resin 128 to forming the interconnect pattern part 132 are repeated to obtain a multi-layer interconnect substrate.

However, according to this manufacturing method, in order to ensure the thickness of the interconnect pattern part 132 in consideration of the alleviation of stress caused by mismatch of the thermal expansion coefficient with the core substrate 120 and the reliability of the multi-layer interconnect substrate such as the connection via part reliability, a photoresist or a dry film having a thickness of about 20 to 40 μm must be used. Therefore, in forming the pattern in the exposure and development process, about 30 μm has been a limit even with the minimum pitch. As a result of this, there have been problems such that the high densification of the multi-layer interconnect substrate and the scale reduction of the substrate shape cannot be promoted.

Also, typically in the production of a build-up substrate, a technique is adopted such that the products are fabricated collectively on a large panel having a size of about 500 mm×600 mm, and individual single multi-layer interconnect substrates are taken out by performing a cutting process in the final step. Therefore, if the outer dimension of the single multi-layer interconnect substrates can be reduced in size, the number of substrates that can be taken out per one panel can be increased. However, in the current method of manufacturing a build-up substrate, the interconnect pattern pitch can be made to be only about 30 μm at the minimum, as described above. For this reason, the outer dimension of the single multi-layer interconnect substrates cannot be reduced, so that it has been difficult to reduce the costs of the multi-layer interconnect substrates to a large extent.

Such a method of manufacturing the multi-layer interconnect substrates further has a problem of warpage. The core substrate itself has warpage, and the mismatch of the resist pattern is induced by the existing warpage in the exposure and development process for forming the build-up interconnect pattern. The mismatch of the resist pattern will invite the decrease in the production yield.

Also, in order to restrain the warpage of the core substrate, a build-up layer must be formed on both sides of the core substrate, thereby necessitating the forming of the build-up interconnect layers that are not originally needed. As a result of this, it will be an organic-based multi-layer interconnect substrate that is compelled layer multiplication more than needed. This induces decrease in the production yield, and it has been extremely difficult to reduce the production costs thereof.

In contrast, according to the interconnect substrate 10 and the semiconductor device 1 of the present embodiment described above as well as the production method thereof, all of the problems associated with the conventional techniques described in FIGS. 14A to 16C can be solved.

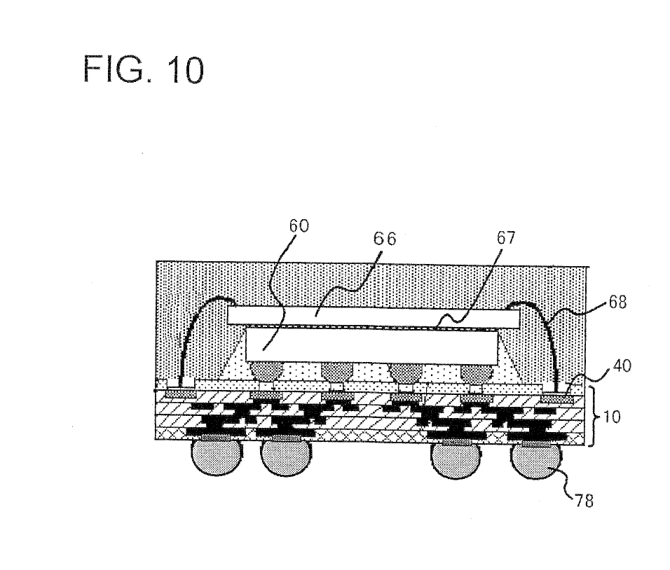

The interconnect substrate and the semiconductor device according to the present invention as well as the production method thereof are not limited to the above-described embodiments, so that various modifications can be made. For example, referring to FIG. 10, a semiconductor chip 66 (second semiconductor chip) may be disposed on the semiconductor chip 60 (first semiconductor chip). The semiconductor chip 66 is stacked on the back surface of the semiconductor chip 60 via an adhesive 67. Also, the semiconductor chip 66 is connected to the electrode pad 10 via a bonding wire 68. With such a construction, a semiconductor device of multiple chip type can be obtained. Also, when a semiconductor chip having a different function from the semiconductor chip 60 is used as the semiconductor chip 66, multiplication of functions of the semiconductor device can be achieved. Here, in the present example, semiconductor chips are stacked in two stages; however, the semiconductor chips may be stacked in three or more stages.

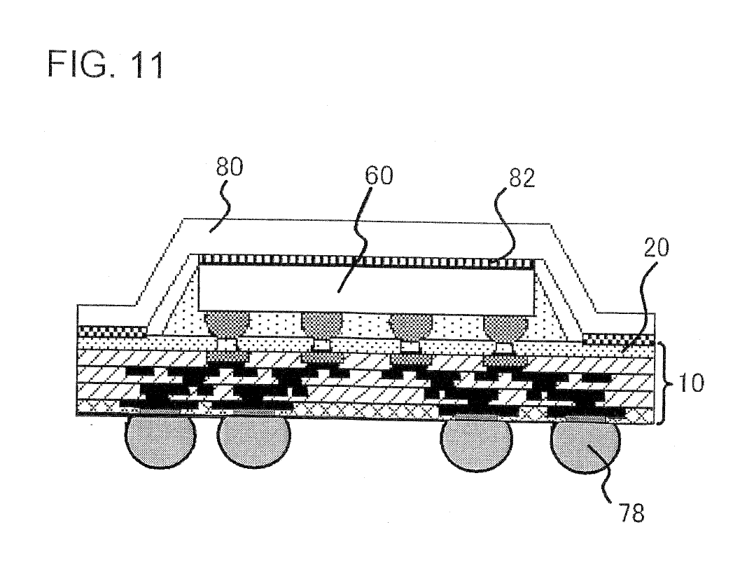

Also, referring to FIG. 11, a heat sink 80 may be disposed on the semiconductor chip 60. The heat sink 80 is connected to the back surface of the semiconductor chip 60 via an adhesive 82. As the adhesive 82, those having a high thermal conductivity are preferably used. Also, the heat sink 80 is disposed on a region from the semiconductor chip 60 to the non-photosensitive resin layer 20, and the part disposed on the semiconductor chip 60 protrudes relative to the part disposed on the non-photosensitive resin layer 20. With such a construction, a semiconductor device being excellent in heat dissipation can be obtained. Generally, flip-chip type semiconductor chips are often multiple-pin and high-speed logic devices, so that it is important to allow the heat generated from the semiconductor chip to be dissipated with a good efficiency.

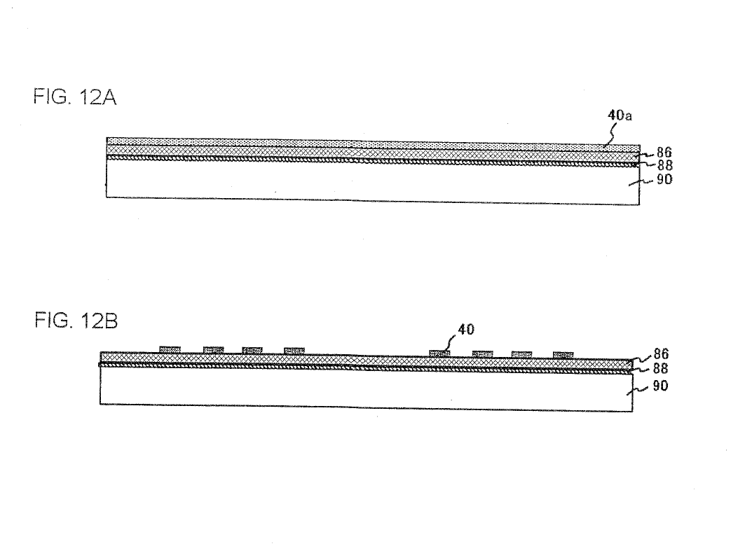

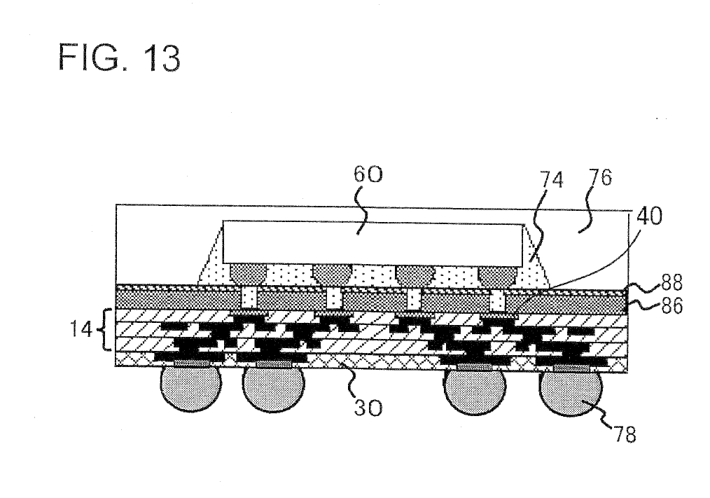

Also, referring to FIG. 12A, in the step of forming the first layer, a non-photosensitive insulating film 86 may be bonded as the first layer onto the base substrate 90 via an insulating adhesive 88. As the insulating film 86, those having a high strength and a high elongation property are preferably used. In FIG. 12A, a Cu foil 40a is formed on the insulating film 86. Namely, on the base substrate 90, an RCC (resin coated copper) with an adhesive, which is made of a multi layer structure of Cu foil 40a/insulating film 86/insulating adhesive 88 is disposed. By performing a patterning process on this Cu foil 40a, the electrode pad 40 can be formed (FIG. 12B). The process of patterning the Cu foil 40a can be performed by adopting a subtractive technique by which a predetermined part of the Cu foil 40a is removed by etching after forming a photoresist and performing an exposure and development process. Thereafter, the steps described in FIGS. 4A to 9C are carried out to obtain a semiconductor device shown in FIG. 13.

According to such a construction, the insulating adhesive 88 functions as an adhesive to the base substrate 90, so that a non-photosensitive insulating film having a larger thickness (for example, about 10 to 30 μm) as compared with the non-photosensitive resin layer 20 described in FIG. 1 and without having an adhesive function such as a high-strength PI film or liquid crystal polymer can be used as the first layer. A non-photosensitive PI film generally has mechanical properties with a breakage strength of 100 MPa or higher and a breakage elongation ratio of 100% or higher, thus having a crack-resistance property of the maximum level among the currently existing insulating materials. For this reason, a coreless-type multi-layer interconnect substrate being further excellent in the resin crack-resistance property can be obtained.

Here, in the above-described RCC, an insulating adhesive may be present between the Cu foil 40a and the insulating film 86. Namely, this RCC may be made of a multi-layer structure of Cu foil 40a/insulating adhesive/insulating film 86/insulating adhesive 88.

It is apparent that the present invention is not limited to the above embodiment, and may be modified and changed without departing from the scope and spirit of the invention.

1. A method of manufacturing an interconnect substrate, comprising:
forming a first layer constructed with a non-photosensitive insulating material on a supporting substrate;
forming a first electrode pad on said first layer;
forming an interconnect and an insulating layer covering said interconnect on said first electrode pad;
forming a second electrode pad on said insulating layer;
forming a second layer constructed with a photosensitive insulating material so as to cover said second electrode pad;
forming a second opening in said second layer so that said second electrode pad is exposed;
removing said supporting substrate after forming said second opening; and
forming a first opening in said first layer after removing said supporting substrate so that said first electrode pad is exposed, said first opening having an opening area smaller than that of said second opening.

2. The method of manufacturing an interconnect substrate as set forth in claim 1,
wherein in said forming of said second opening, said second opening is formed by photolithography method, and
in said forming of said first opening, said first opening is formed by laser processing.

3. The method of manufacturing an interconnect substrate as set forth in claim 1,
wherein, in said forming of said first layer, a non-photosensitive insulating film is bonded, as said first layer, onto said supporting substrate through an intermediary of an insulating adhesive.

4. A method of manufacturing a semiconductor device, comprising:
forming a first layer constructed with a non-photosensitive insulating material on a supporting substrate;
forming a first electrode pad on said first layer;
forming an interconnect and an insulating layer covering said interconnect on said first electrode pad;
forming a second electrode pad on said insulating layer;
forming a second layer constructed with a photosensitive insulating material so as to cover said second electrode pad;
forming a second opening in said second layer so that said second electrode pad is exposed;
removing said supporting substrate after forming said second opening;
forming a first opening in said first layer after removing said supporting substrate so that said first electrode pad is exposed, said first opening having an opening area smaller than that of said second opening; and
connecting a semiconductor chip to said first electrode pad that is exposed to said first opening.
